(19) United States
(12) Patent Application Publication
(10) Pub. No.: US 2026/0169688 A1
(43) Pub. Date: Jun. 18, 2026

(54) DATA-DEPENDENT INDUCED GLITCH MITIGATION FOR HIGH-SPEED SERIALIZERS

(71) Applicant: QUALCOMM Incorporated, San Diego, CA (US)

(72) Inventors: Chung-Ching LIN, San Diego, CA (US); Alireza MAHMOODI, San Diego, CA (US)

(21) Appl. No.: 18/985,886

(22) Filed: Dec. 18, 2024

(51) Int. Cl. G06F 5/16; G06F 1/06; H03K 3/037; H03K 5/135; H03M 9/00; H04J 3/04

(52) U.S. Cl. CPC G06F 5/16; G06F 1/06; H03K 3/037; H03K 5/135; H03M 9/00; H04J 3/047

(57) ABSTRACT

A serializer circuit includes flipflops and a multiplexing circuit. A first flipflop may be configured to capture a bit of data from a first data signal during each cycle of a clock signal. A second flipflop may be configured to capture a bit of data from a second data signal during each cycle of the clock signal. The multiplexing circuit may be configured to provide an output of the first flipflop as an output of the multiplexing circuit when a delayed version of the clock signal is in a first signaling state, and to provide an output of the second flipflop as the output of the multiplexing circuit when the delayed version of the clock signal is in a second signaling state. The delayed version of the clock signal may be configured to suppress data-dependent glitches in an output signal used in subsequent stages of a receiving device.

### TECHNICAL FIELD

The present disclosure generally relates to interfaces between voltage domains and, more particularly, to data capture circuits that can accommodate different timing specifications defined for multiple voltage domains.

### BACKGROUND

Electronic device technologies have seen explosive growth over the past several years. For example, growth of cellular and wireless communication technologies has been fueled by better communications, hardware, larger networks, and more reliable protocols. Wireless service providers are now able to offer their customers an ever-expanding array of features and services, and provide users with unprecedented levels of access to information, resources, and communications. To keep pace with these service enhancements, mobile electronic devices have become more powerful and complex than ever. Wireless devices often include a high-speed bus interface for communication of signals between hardware components. For example, the high-speed bus interface may be implemented using a Peripheral Component Interconnect Express (PCIe) bus, Universal Serial Bus (USB) or Serial Advanced Technology Attachment (SATA), among others.

Integrated circuit (IC) devices may include a serializer/deserializer (SERDES) to transmit and receive through a communication link. In high-speed applications, timing of the operation of a SERDES may be controlled by one or more clock signals. In certain implementations, a high-speed serial bus interface may be configurable for different modes of communication. For example, IC devices that include memory interfaces have physical layer circuits may be expected to operate in one or more high-speed data communication modes and one or more low-speed data communication modes. Different signaling voltages may be defined for high-speed and low-speed data communication modes. Increased demands for higher data rates require increasingly tight timing between circuits within the memory interface in order to ensure integrity of the data and clock signals between memory controller and memory devices.

Increasing demand for greater functionality in apparatus including cellular telephones, smart phones, global positioning satellite navigators, media players and the like requires the development of semiconductor IC devices that have higher circuit density and which switch at higher frequencies to provide increased functionality and speed of operation within specified power budgets. Advances in speed and size may be accomplished through the use of IC devices fabricated with decreased process geometries and/or lowered operating voltages. Decreased process technologies and increased data transmission rates tend to impact timing margins and tighter timing requirements may be imposed on circuit switching speeds. Accordingly, there is an ongoing need for improved performance, accuracy and/or reliability of interface circuits.

### SUMMARY

Certain aspects of the disclosure relate to systems, apparatus, methods and techniques that can be used in integrated circuit (IC) devices that include high-speed data communication interfaces. In one aspect, sequential logic circuits may be configured to reliably sample or capture data. The sequential logic circuits may generate or use clock signals that are configured to accommodate differences in propagation delays of transitions initiated by edges in clock signals.

In various aspects of the disclosure, a serializer circuit includes flipflops and a multiplexing circuit. A first flipflop may be configured to capture a bit of data from a first data signal during each cycle of a clock signal. A second flipflop may be configured to capture a bit of data from a second data signal during each cycle of the clock signal. The multiplexing circuit may be configured to provide an output of the first flipflop as an output of the multiplexing circuit when a delayed version of the clock signal is in a first signaling state, and to provide an output of the second flipflop as the output of the multiplexing circuit when the delayed version of the clock signal is in a second signaling state.

In various aspects of the disclosure, an apparatus includes means for capturing data bits from a plurality of datastreams during each cycle of a clock signal, and means for transmitting the data bits in sequential bit transmission intervals through a first output of the apparatus. The means for transmitting the data bits may be configured to respond to a delayed version of the clock signal. The data bits may be captured from a first data signal that encodes a bitstream comprising even bits of a first parallel data element and a second data signal that encodes a bitstream comprising odd bits of the first parallel data element.

In various aspects of the disclosure, a method for serializing data includes capturing first data bits from a first data signal during each cycle of a clock signal. The first data signal may encode a bitstream comprising even bits of a parallel data element. The method further includes capturing second data bits from a second data signal during each cycle of the clock signal. The second data signal may encode a bitstream comprising odd bits of the parallel data element. The method further includes providing the clock signal as an input to a delay circuit that is implemented using one or more series-coupled inverters, and multiplexing the first data bits and the second data bits into an output signal in accordance with timing provided by a delayed clock signal output by the delay circuit. In one example, the first data signal encodes even bits of a parallel data element and the second data signal encodes odd bits of the parallel data element.

In certain examples, the multiplexing circuit includes transmission gates. A first transmission gate may be configured to couple the output of the first flipflop to the output of the multiplexing circuit when the delayed version of the clock signal is in the first signaling state. A second transmission gate may be configured to couple the output of the second flipflop to the output of the first multiplexing circuit when the delayed version of the clock signal is in the second signaling state. In one example, the clock signal may be provided as a differential signal that includes the delayed version of the clock signal and an inverted delayed version of the clock signal.

In certain examples, a delay circuit has an input that is coupled to the clock signal and an output that provides the delayed version of the clock signal. The delay circuit may be implemented using one or more serially-coupled inverters. The serially-coupled inverters may be configured to delay the clock signal by a duration comparable to a propagation delay through the first flipflop or through the second flipflop. A third flipflop may be configured to capture a bit of data from a third data signal during each cycle of the clock signal. A fourth flipflop may be configured to capture a bit of data from a fourth data signal during each cycle of the clock signal.

In certain examples, a second multiplexing circuit may be configured to provide an output of the third flipflop as an output of the second multiplexing circuit when a delayed version of the clock signal is in the first signaling state and to provide an output of the fourth flipflop as the output of the second multiplexing circuit when the delayed version of the clock signal is in the second signaling state. The first data signal may encode even bits of a first parallel data element and the second data signal may encode odd bits of the first parallel data element. The third data signal may encode even bits of a second parallel data element and the fourth data signal encodes odd bits of the second parallel data element. The second multiplexing circuit may include transmission gates. A third transmission gate may be configured to couple the output of the third flipflop to the output of the second multiplexing circuit when the delayed version of the clock signal is in the first signaling state. A fourth transmission gate may be configured to couple the output of the fourth flipflop to the output of the second multiplexing circuit when the delayed version of the clock signal is in the second signaling state.

### BRIEF DESCRIPTION OF THE DRAWINGS

FIG. 1 illustrates an example of a system-on-a-chip (SOC) that may be adapted in accordance with certain aspects of the present disclosure.

FIG. 2 illustrates an example of a data communication interface that may be adapted in accordance with certain aspects of the present disclosure.

FIG. 3 illustrates certain aspects of timing defined for sequential logic circuits, including circuits in a multi-rail memory device.

FIG. 4 illustrates certain aspects of a multipath circuit provided within a serializer.

FIG. 5 includes a timing diagram provides a more detailed illustration of certain aspects of the timing associated with signaling transitions in the multipath circuit illustrated in FIG. 4.

FIG. 6 illustrates certain aspects of a multipath circuit provided in accordance with certain aspects of this disclosure.

FIG. 7 illustrates a multipath circuit that can mitigate propagation delay differences in a multichannel a high-speed communication link implemented in accordance with certain aspects of this disclosure.

FIG. 8 is a flow diagram illustrating an example of a method for serializing data in accordance with certain aspects disclosed herein.

### DETAILED DESCRIPTION

The detailed description set forth below in connection with the appended drawings is intended as a description of various configurations and is not intended to represent the only configurations in which the concepts described herein may be practiced. The detailed description includes specific details for the purpose of providing a thorough understanding of various concepts. However, it will be apparent to those skilled in the art that these concepts may be practiced without these specific details. In some instances, well-known structures and components are shown in block diagram form in order to avoid obscuring such concepts.

With reference now to the Figures, several exemplary aspects of the present disclosure are described. The word “exemplary” is used herein to mean “serving as an example, instance, or illustration.” Any aspect described herein as “exemplary” is not necessarily to be construed as preferred or advantageous over other aspects.

The terms “computing device” and “mobile device” are used interchangeably herein to refer to any one or all of servers, personal computers, smartphones, cellular telephones, tablet computers, laptop computers, notebooks, ultrabooks, palm-top computers, personal data assistants (PDAs), wireless electronic mail receivers, multimedia Internet-enabled cellular telephones, Global Positioning System (GPS) receivers, wireless gaming controllers, and similar personal electronic devices which include a programmable processor. While the various aspects are particularly useful in mobile devices (e.g., smartphones, laptop computers, etc.), which have limited resources (e.g., processing power, battery, size, etc.), various aspects are generally useful in any computing device that may benefit from improved performance and design flexibility.

The term “multicore processor” is used herein to refer to a single integrated circuit (IC) chip or chip package that contains two or more independent processing units or cores (e.g., CPU cores, etc.) configured to read and execute program instructions. The term “multiprocessor” is used herein to refer to a system or device that includes two or more processing units configured to read and execute program instructions.

The term “system on chip” (SoC) is used herein to refer to a single integrated circuit (IC) chip that contains multiple resources and/or processors integrated on a single substrate. A single SoC may contain circuitry for digital, analog, mixed-signal, and radio-frequency functions. A single SoC may also include any number of general purpose and/or specialized processors (digital signal processors (DSPs), modem processors, video processors, etc.), memory blocks (e.g., read only memory (ROM), random access memory (RAM), flash, etc.), and resources (e.g., timers, voltage regulators, oscillators, etc.), any or all of which may be included in one or more cores.

Process technology employed to manufacture semiconductor devices, including IC devices is continually improving. Process technology includes the manufacturing methods used to make IC devices and defines transistor size, operating voltages and switching speeds. Features that are constituent elements of circuits in an IC device may be referred as technology nodes and/or process nodes. The terms technology node, process node, process technology may be used to characterize a specific semiconductor manufacturing process and corresponding design rules. Faster and more power-efficient technology nodes are being continuously developed through the use of smaller feature size to produce smaller transistors that enable the manufacture of higher-density ICs.

Memory technologies may be suitable for storing instructions, programs, control signals, and/or data for use in or by a computer or other digital electronic device. Any references to terminology and/or technical details related to an individual type of memory, interface, standard, or memory technology are for illustrative purposes only, and not intended to limit the scope of the claims to a particular memory system or technology unless specifically recited in the claim language. Mobile computing device architectures have grown in complexity, and now commonly include multiple processor cores, SoCs, co-processors, functional modules including dedicated processors (e.g., communication modem chips, GPS receivers, etc.), complex memory systems, intricate electrical interconnections (e.g., buses and/or fabrics), and numerous other resources that execute complex and power intensive software applications (e.g., video streaming applications, etc.).

In many implementations, an IC device may include and/or distinguish between internal core circuits, peripheral circuits, I/O circuits, memory and other circuits. The internal core circuits may be included in a section of the IC that may be referred to simply as a “core” that performs certain functions including storing data (memory), managing stored data, performing certain logic functions, processing-specific functions, cryptography, image processing and so on. More than one section of an IC may be defined as a core. In many examples, the devices and/or circuits in a core may be configurable to operate at the highest possible operating frequency enabled by the process technology. In many examples, the operating frequency of circuits in a core may be constrained by a power budget and the operating frequency of some core circuits may be configured to obtain fastest operation within the power budget. Lower power consumption in high-speed circuits can be achieved by reducing the operating voltage of the core, and process technologies have been evolving to support ever-lower core operating voltages.

An IC device typically receives power from an external power supply. Examples of external power supplies include batteries, solar cells or solar panels, switching power supplies and other types of power converters. The external power supply may provide power at different voltage levels, where the voltage levels are measured with respect to a ground reference. In one example, the ground reference may be designated to be a zero-volt level. Multiple power rails may be provided to carry current to or from the power supply. Each power rail provides a low resistance path for current flows and each power rail may be implemented using one or more wires, connectors, interconnects, traces on a circuit board or the like. The IC device may be coupled to two or more of the power rails and may extend these power rails internally using low-impedance interconnects or conductive planes with the IC structure. The internal power rails conduct current to the various sections of the IC device at a voltage level defined for the respective power rails.

In some examples, the internal power rails may be referred to as internal power sources or power sources, although the power rails may serve as conduits for external power sources. In some examples, internal power sources may include internal power rails that are driven by power conditioning circuits, power conversion circuits or circuits that step up or step down voltage levels for use within the IC device. In some examples, the internal power rails may be labeled according to usage. In some examples, the ground reference of an IC device or of a section of an IC device may be labeled Voltage-Source-Source (Vₛₛ), and non-zero power rails may be labeled Voltage-Drain-Drain (V_{dd}). In many examples, the IC may provide multiple V_{dd} power rails, labeled V_{dd}1, V_{dd}2, V_{dd}3, . . . V_{dd}X, etc. The ground reference may provide a return path for currents flowing through the IC device.

Certain aspects of the disclosure are applicable to serializer/deserializer (SERDES) circuits used to transmit and receive data over a serial communication link. SERDES circuits may be included in certain input/output (I/O) circuits. For example, SERDES circuits may be used in an IC device that provide an interface between core circuits and memory devices. Many mobile devices employ Synchronous Dynamic Random Access Memory (SDRAM), including Low-Power Double Data Rate (DDR) SDRAM, which may be referred to as low-power DDR SDRAM, LPDDR SDRAM or, in some instances, LPDDRx where x describes the technology generation of the LPDDR SDRAM. Later generations of LPDDR SDRAM designed to operate at higher operating frequencies.

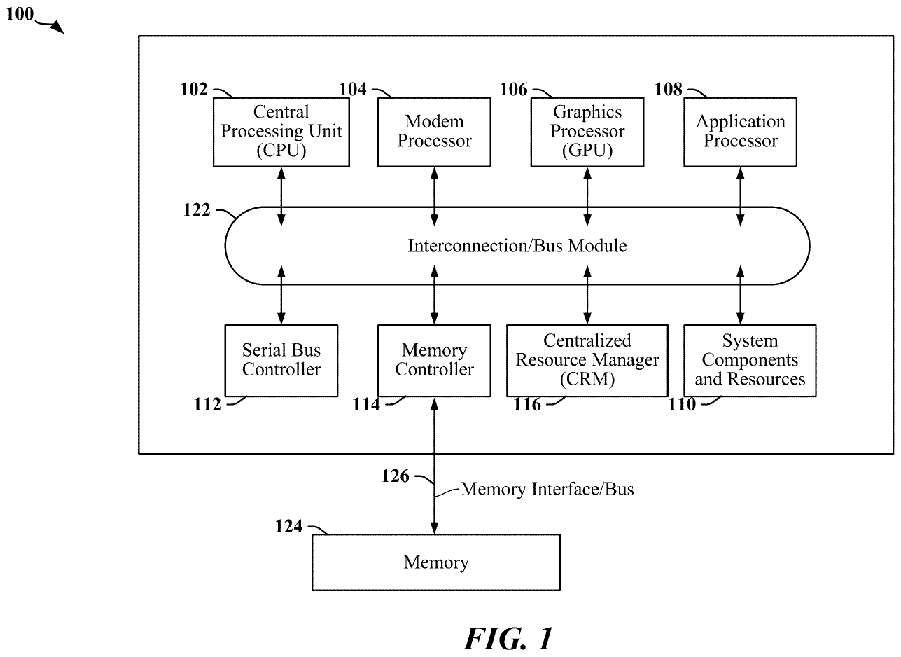

FIG. 1 illustrates an example of components and interconnections in a system-on-chip (SoC) 100, including a memory interface/bus 126, that may be suitable for implementing certain aspects of the present disclosure. The SoC 100 may include a number of heterogeneous processors, such as a central processing unit (CPU) 102, a modem processor 104, a graphics processor 106, and an application processor 108. Each processor 102, 104, 106, 108, may include one or more cores, and each processor/core may perform operations independent of the other processors/cores. The processors 102, 104, 106, 108 may be organized in close proximity to one another (e.g., on a single substrate, die, integrated chip, etc.) so that the processors may operate at a much higher frequency/clock rate than would be possible if the signals were to travel off-chip. The proximity of the cores may also allow for the sharing of on-chip memory and resources (e.g., power rails), as well as for more coordinated cooperation between cores.

The SoC 100 may include system components and resources 110 for managing sensor data, analog-to-digital conversions, and/or wireless data transmissions, and for performing other specialized operations (e.g., decoding high-definition video, video processing, etc.). System components and resources 110 may also include components such as voltage regulators, oscillators, phase-locked loops (PLLs), peripheral bridges, data controllers, system controllers, access ports, timers, and/or other similar components used to support the processors and software clients running on the computing device. The system components and resources 110 may also include circuitry for interfacing with peripheral devices, such as cameras, electronic displays, wireless communication devices, external memory chips, etc.

The SoC 100 may further include a Universal Serial Bus (USB) or other serial bus controller 112, one or more memory controllers 114, and a centralized resource manager (CRM) 116. The SoC 100 may also include an input/output module (not illustrated) for communicating with resources external to the SoC, each of which may be shared by two or more of the internal SoC components.

The processors 102, 104, 106, 108 may be interconnected to the USB controller 112, the memory controller 114, system components and resources 110, CRM 116, and/or other system components via an interconnection/bus module 122, which may include an array of reconfigurable logic gates and/or implement a bus architecture. Communications may also be provided by advanced interconnects, such as high performance networks on chip (NoCs).

The interconnection/bus module 122 may include or provide a bus mastering system configured to grant SoC components (e.g., processors, peripherals, etc.) exclusive control of the bus (e.g., to transfer data in burst mode, block transfer mode, etc.) for a set duration, number of operations, number of bytes, etc. In some cases, the interconnection/bus module 122 may implement an arbitration scheme to prevent multiple master components from attempting to drive the bus simultaneously. The memory controller 114 may be a specialized hardware module configured to manage the flow of data to and from a memory 124 via the memory interface/bus 126.

The memory controller 114 may comprise one or more processors configured to perform read and write operations with the memory 124. Examples of processors include microprocessors, microcontrollers, digital signal processors (DSPs), field programmable gate arrays (FPGAs), programmable logic devices (PLDs), state machines, gated logic, discrete hardware circuits, and other suitable hardware configured to perform the various functionality described throughout this disclosure. In certain aspects, the memory 124 may be part of the SoC 100.

The memory 124 may be implemented using memory devices that can be configured to operate in accordance with specifications defining the operational characteristics of multiple types of LPDDRi SDRAM. In one example, a memory device may be operated in LPDDR2 SDRAM and LPDDR4X SDRAM modes of operation, which may be referred to herein as the “LP2” and “LP4X” modes, respectively. The memory device includes double data rate input/output circuits (DDRIO) that enable the memory device to communicate with corresponding I/O circuits in the SoC 100 or another device coupled to the memory device. The DDRIO may be configurable for multi-mode operation. In some instances, a transmitter in the DDRIO of a memory device that supports LP2 and LP4X modes of operation may include multiple circuits that perform the same function at different voltage levels.

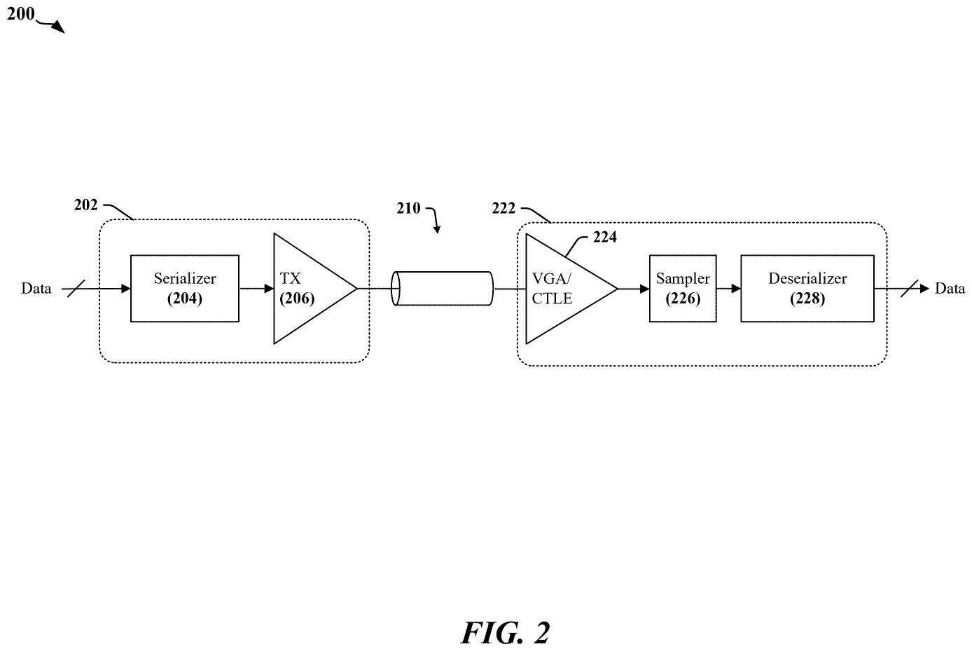

FIG. 2 illustrates an example of a data communication system 200 that may be adapted in accordance with certain aspects of the present disclosure. The data communication system 200 includes a transmitter 202, a data communication channel 210, and a receiver 222. The transmitter 202 may be provided in a first device that is configured to transmit a data signal to a second device. The data communication channel 210 provides a transmission medium through which the data signal propagates from the first device to the second device. The receiver 222 may be provided in the second device and may be configured to receive and process the data signal.

In one example, the transmitter 202 includes a serializer 204 configured to convert parallel data into serial data. The transmitter 202 further includes a transmit driver 206 configured to generate a data signal based on the serial data for transmission to the receiver 222 through the data communication channel 210.

The data communication channel 210 may be implemented using any type of transmission medium by which a data signal can propagate from the transmitter 202 to the receiver 222. Examples of the data communication channel 210 include one or more wires including twisted pairs of wires, metallization traces (which may include one or more vias) on a printed circuit board (PCB), stripline, microstrip, and/or coaxial cable.

In the illustrated example, the receiver 222 includes a VGA with a continuous time linear equalizer (CTLE), a sampler circuit 226 and a deserializer 228. The combined VGA and CTLE circuit may be referenced herein as the VGA/CTLE 224. Continuous time linear equalization may be configured to boost higher frequency components of a received data signal in order to bring all frequency components of the received data signal to a similar amplitude ratio before channel attenuation, improving jitter performance. The VGA/CTLE 224 may be configured to perform equalization and amplification of the received data signal. The sampler circuit 226 is configured to recover data from the received data signal using timing information provided by a clock signal associated with the received data signal. The deserializer 228 is configured to convert the recovered data into parallel data.

In high-speed applications, data throughput of a serial data link may be limited by a combination of factors that may include switching speed of circuits in the transmitter or receiver and the characteristics of the channel used to carry data signals, for example. Impedance mismatches, parasitic electromagnetic coupling and other factors can cause signal distortion. In various examples, one or more of the channels may be implemented using one or more metallization traces (which may include one or more vias) on a printed circuit board (PCB), stripline, microstrip, coaxial cable, twisted pairs of wires, etc. In many implementations, equalization circuits and capabilities are included in input/output (I/O) circuits to compensate for signal distortions attributable to inter-symbol interference (ISI) and other effects that can combine to limit bandwidth in a channel. ISI can result when a first-received symbol interferes with subsequently received symbols due to reflections, frequency-dependent delays and other imperfections in the channel. A symbol may refer to signaling state within a unit interval (UI), or symbol interval, in which data is modulated or encoded in the waveform of a transmitted signal. In one example, a data bit may be transmitted over a channel or path of a communication link in one bit transmission interval. The terms “bit transmission interval” and “UI” may be used interchangeably in reference to certain data communication links.

Certain aspects of this disclosure can optimize performance of logic circuits in high-speed SERDES. In one aspect, power consumption may be reduced. In one aspect, signal timing may be optimized such that hold times and setup times for sequential logic may be met at higher signaling frequency. For the purposes of this disclosure, a sequential logic circuit refers to a logic circuit that has outputs that are state dependent. In one example, certain flipflops propagate their inputs through to their outputs when a clock signal is in a first signaling state, and then hold or lock their outputs when the clock signal is in a second signaling state. In another example, certain flipflops propagate their inputs through to their outputs when a specified transition between signaling states (e.g., a negative-going or positive-going edge) occurs in the clock signal, and then hold or lock their outputs until the next specified transition between signaling states.

Certain aspects of this disclosure relate to timing and synchronization between multiplexing circuits and sequential logic circuits in a SERDES that uses a half-rate clock signal. The term “half-rate clock signal” or “half-rate interface” as used herein refers to the use of a clock signal with a frequency that corresponds to half the rate at which data is received. Half-rate clock signals have a period that is twice the duration of the UI in which a data bit can be encoded in the data signal. For example, one bit of data may be transmitted or received in a bit transmission interval that has a duration that corresponds to a half cycle of a clock signal transmitted over a data communication link. The use of a half-rate clock signal can significantly reduce power consumption in a SERDES circuit with respect to conventional SERDES circuits.

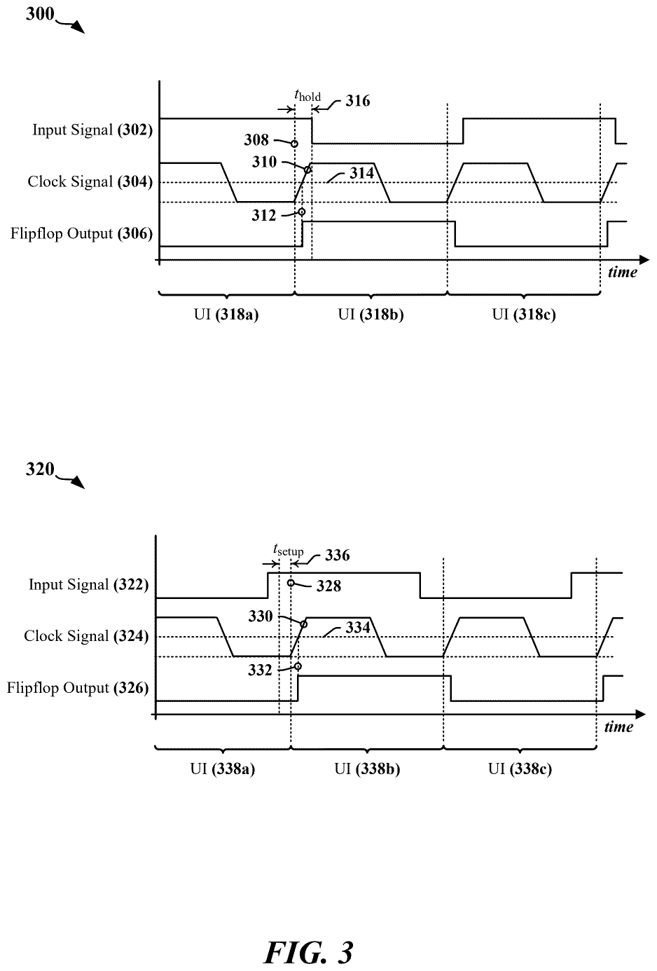

FIG. 3 illustrates timing examples 300, 320 defined for a sequential logic circuit such as a latch or flipflop. For the purposes of this disclosure, the term “sequential logic circuit” refers to a logic circuit that has outputs that are state dependent. The illustrated timing examples 300, 320 relates in certain aspects to the operation of a flipflop that has an output that reflects the signaling state of its input when an edge occurs in a clock signal.

In the first illustrated timing example 300, the sequential logic circuit receives an input signal 302 that is toggling between higher voltage and lower voltage signaling states in consecutive bit transmission intervals. Bit transmission intervals may also be referred to as unit intervals (e.g., UI 318a, UI 318b and UI 318c). The sequential logic circuit may be configured to capture the signaling state of the input signal 302 based on timing provided by a clock signal 304. In the illustrated example, the sequential logic circuit provides an output signal 306 that represents the signaling state of the input signal 302 captured at rising edges in the signaling state of the clock signal 304. For the purposes of this disclosure, a rising edge is a transition from a lower voltage signaling state to a higher voltage signaling state.

In the first illustrated timing example 300, a rising edge 310 in the clock signal 304 commences at a first point in time 308. Latching circuits in the sequential logic circuit may be switched at a second point in time 312 after the signaling state of the clock signal 304 crosses a threshold voltage level 314. In this example, the threshold voltage level 314 is depicted as a voltage level that is substantially halfway between the higher voltage and lower voltage signaling states. In other examples, the threshold voltage level 314 may be closer to the higher voltage signaling state or to the lower voltage signaling state. The input signal 302 is expected to remain constant for a duration of time that is sufficient to enable the signaling state of the clock signal 304 to reach the threshold voltage level 314 such that the signaling state of the input signal 302 is reliably captured. Accordingly, a nominal minimum hold time 316 is typically specified for the input signal 302 to ensure reliable operation of the sequential logic circuit.

If the timing of the input signal 302 does not comply with the nominal minimum hold time 316, then the sequential logic circuit may capture a data bit from the next bit transmission interval. In the illustrated example, the sequential logic circuit captures signaling state from UI 318a in a compliant input signal 302 but may incorrectly capture signaling state from UI 318b when the input signal 302 does not maintain signaling state during the nominal minimum hold time 316.

In the second illustrated timing example 320, the sequential logic circuit receives an input signal 322 that is toggling between higher voltage and lower voltage signaling states in consecutive bit transmission intervals. The input signal 322 is delayed with respect to a clock signal 324 that defines bit transmission intervals (e.g., UI 338a, UI 338b and UI 338c). The sequential logic circuit may be configured to capture the signaling state of the input signal 322 based on timing provided by the clock signal 324. In the illustrated example, the sequential logic circuit provides an output signal 326 that represents the signaling state of the input signal 322 captured at rising edges in the signaling state of the clock signal 324. In this example, the input signal 322 transitions late in each UI 338a, UI 338b and UI 338c, but before corresponding rising edges in the clock signal 324.

In one example, a rising edge 330 in the clock signal 324 commences at a first point in time 328. Latching circuits in the sequential logic circuit may be switched at a second point in time 332 after the signaling state of the clock signal 324 crosses a threshold voltage level 334. In this example, the threshold voltage level 334 is depicted as a voltage level that is substantially halfway between the higher voltage and lower voltage signaling states. In other examples, the threshold voltage level 334 may be closer to the higher voltage signaling state or to the lower voltage signaling state. The input signal 322 is expected to be stable and in the intended signaling state for a duration of time that enables a signal to propagate through at least an input stage of the sequential logic circuit before the signaling state of the clock signal 324 reaches the threshold voltage level 334 in order to permit the signaling state of the input signal 322 to be reliably captured. Accordingly, a nominal minimum setup time 336 is typically specified for the input signal 322 to ensure reliable operation of the sequential logic circuit. If the timing of the input signal 322 does not comply with the nominal minimum setup time 336, then the sequential logic circuit may propagate a data bit from the previous bit transmission interval.

Sequential logic circuits may be combined with multiplexers and demultiplexers in high speed SERDES circuits. As clock frequencies increase, the timing margins available for sequential logic decrease. Minimum hold and setup times remain constant while clock periods decrease such that the minimum hold and setup times account for an ever-increasing proportion of the UI.

Certain SERDES circuits are designed with a multipath architecture whereby even and odd bits of a parallel data word are propagated through separate serializing circuits and output during different signaling states in a clock signal. The division between even and odd bits enables each path to operate at half the specified SERDES clock frequency. In one example, an even path processes data bits that are identified using even numbers and the odd path processes data bits that are identified using odd numbers. An even number may be defined by the expression Numₑᵥₑₙ=2i, and an odd number may be defined by the expression Num_{odd}=2i+1, where i represents an integer value. Parallel data bits may be labeled according to position in a word (e.g., D0, D1, D2, . . . , D15), byte or other value. In this example, the even path of the DFE handles the even bits (D0, D2, D4, . . . , D14) of a serialized word and the odd path of the DFE handles the odd bits (D1, D3, D5, . . . , D15) of the serialized word.

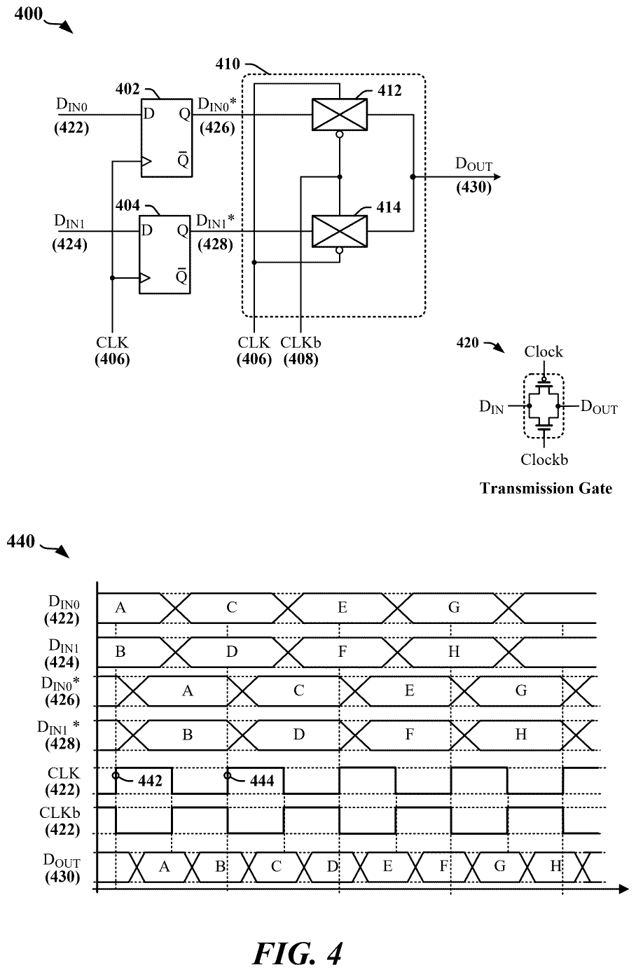

FIG. 4 illustrates certain aspects of a multipath circuit 400 provided within a serializer. Flipflop-based serializers are used in many wireline systems to convert parallel data into a serialized bit stream. In a muti-path serializer, even and odd bits are propagated through flipflops deployed in corresponding even and odd paths and combined using a multiplexer. The illustrated multipath circuit 400 includes two flipflops 402, 404 and a multiplexing circuit 410 that is implemented using transmission gates 412, 414.

In the illustrated example, a first flipflop 402 is configured to capture the signaling state of a D_{IN0} signal 422 at rising edges of a CLK signal 406, and a second flipflop 404 is configured to capture the signaling state of a D_{IN1} signal 424 at rising edges of the CLK signal 406. A first data bitstream encoded in the D_{IN0} signal 422 includes even data bits extracted from a parallel word and a second data bitstream encoded in the D_{IN1} signal 424 includes odd data bits extracted from the parallel word. The first flipflop 402 outputs a sampled version of the first data bitstream in the D_{IN0}*signal 426, which is provided to the input of a first transmission gate 412. The second flipflop 404 outputs a sampled version of the second data bitstream in the D_{IN1}*signal 428, which is provided to the input of a second transmission gate 414.

Each transmission gate 412, 414 is controlled by a complementary pair of clock signals, including the CLK signal 406 and a CLKb signal 408. For the purposes of this disclosure, a complementary pair of signals includes two signals that are phase-shifted versions of each other, where the phase shift between the signals is 180°. In the illustrated example, the CLKb signal 408 is phase shifted by 180° with respect to the CLK signal 406. The CLKb signal 408 may be referred to as an inverted version of the CLK signal 406. One example of a circuit 420 that can be operated as a transmission gate is shown in FIG. 4.

In the illustrated multipath circuit 400, the first transmission gate 412 is enabled when the CLK signal 406 is in a first signaling state and disabled when the CLK signal 406 is in a second signaling state, and a second transmission gate 414 is enabled when the CLKb signal 408 is in the first signaling state and disabled when the CLKb signal 408 is in the second signaling state. The first transmission gate 412 is configured to couple the output of the first flipflop 402 to the output of the serializer when the first transmission gate 412 is enabled. The second transmission gate 414 is configured to couple the output of the second flipflop 404 to the output of the serializer when the second transmission gate 414 is enabled.

In the illustrated example, the CLK signal 406 and the CLKb signal 408 are half-rate clock signals, having a period that is twice the duration of the UI in which a data bit can be encoded in the D_{OUT} signal 430 that is output by the multipath circuit 400. In other words, the frequency of the CLK signal 406 and the CLKb signal 408 is half the frequency of a data clock signal used to transmit or receive bits of data over a communication link in sequential bit transmission intervals.

The timing diagram 440 illustrates certain aspects of the operation of the multipath circuit 400 when sampling occurs at the midpoint between transitions in the D_{IN0} signal 422 and the D_{IN1} signal 424. Even data bits encoded in the D_{IN0} signal 422 include bits A, C, E and G. Odd data bits encoded in the D_{IN1} signal 424 include bits B, D, F and H. At the input of the illustrated multipath circuit 400, the source parallel data has already been split into even and odd paths. The D_{IN0} signal 422 and the D_{IN1} signal 424 may be received from respective predecessor flipflops (not shown).

At a rising edge 442 in the CLK signal 406, the first flipflop 404 captures the signaling state of the D_{IN0} signal 422 and the second flipflop 404 captures the signaling state of the D_{IN1} signal 424. The rising edge 442 leaves the CLK signal 406 in the first signaling state and the CLKb signal 408 in the second signaling state. The first transmission gate 414 is opened and the second transmission gate 414 is closed. The D_{OUT} signal 430 reflects the signaling state at the output of the first flipflop 402. The next falling edge 444 of the CLK signal 406 leaves the CLK signal 406 in the second signaling state and the CLKb signal 408 in the first signaling state. The first transmission gate 414 is then closed and the second transmission gate 414 is opened. The D_{OUT} signal 430 reflects the signaling state at the output of the second flipflop 404.

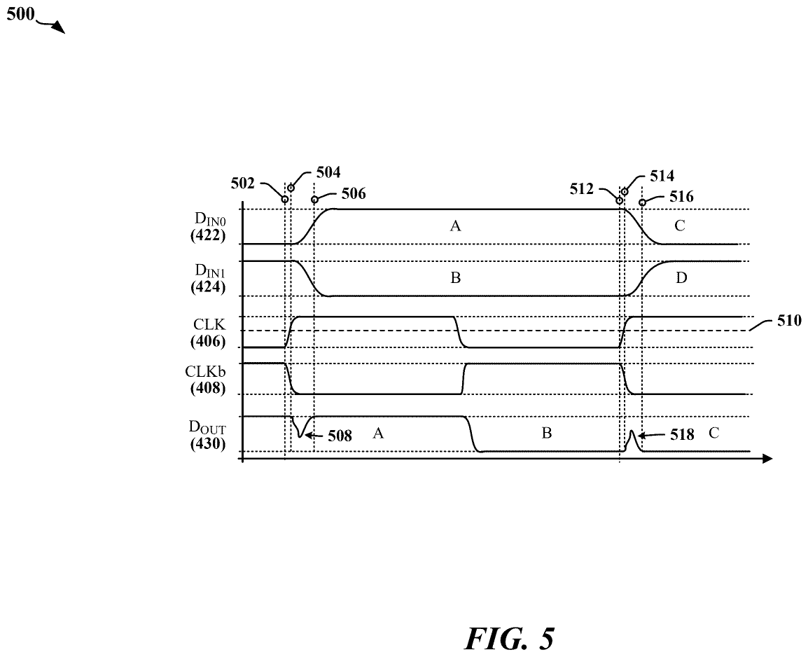

FIG. 5 includes a timing diagram 500 that illustrates certain aspects of the timing associated with signaling transitions in the multipath circuit 400 illustrated in FIG. 4. The timing diagram 500 relates in some respects to the operation of the multipath circuit 400 when sampling occurs concurrently with, or close to transitions in the D_{IN0} signal 422 and/or the D_{IN1} signal 424. Propagation delays incurred through the flipflops 402, 404 can be expected to exceed propagation delays through the transmission gates 412, 414 and this difference in propagation timing can produce momentarily instability in the D_{OUT} signal 430. The instability may produce glitches in the form of spikes or dips in the D_{OUT} signal 430. These glitches can cause transitions or switching in circuits that are coupled to the D_{OUT} signal 430, or that respond to transitions in the D_{OUT} signal 430.

An example of a signaling dip 508 is illustrated in timing diagram 500. In the illustrated example, a rising edge in the CLK signal 406 commences at a first point in time 502. The first transmission gate 412 is enabled and the second transmission gate 412 is disabled when the CLK signal 406 reaches the high signaling state after crossing a threshold voltage level 510 subsequent to the first point in time 502. In the illustrated example, the first transmission gate 412 is enabled at a second point in time 504, before the D_{IN0} signal 422 has propagated through the first flipflop 402. Before the first point in time 502, the D_{OUT} signal 430 is driven by the second transmission gate 414 to the high signaling state. After the second point in time 504, the D_{OUT} signal 430 is driven by the first transmission gate 414, which propagates the D_{IN0}*signal 426. However, the D_{IN0} signal 422 does not propagate through the first flipflop 402 until a third point in time 506 and the first transmission gate 414 drives the D_{OUT} signal 430 to the low signaling state until the D_{IN0} signal 422 has propagated through the first flipflop 402. The duration of the signaling dip 508 reflects the difference between propagation time through the flipflops 402, 404 and propagation time through the transmission gates 412, 414 and may be sufficient to cause other circuits to switch and thereby unnecessarily consume power. In some implementations, the signaling dip 508 may compromise hold or setup times in high-speed interfaces.

An example of a signaling spike 518 is also illustrated in timing diagram 500. In the illustrated example, a rising edge in the CLK signal 406 commences at a fourth point in time 512. The first transmission gate 412 is enabled and the second transmission gate 412 is disabled when the CLK signal 406 reaches the high signaling state after crossing a threshold voltage level 510 subsequent to the fourth point in time 512. In the illustrated example, the first transmission gate 412 is enabled at a fifth point in time 514, before the D_{IN0} signal 422 has propagated through the first flipflop 402. Before the fourth point in time 512, the D_{OUT} signal 430 is driven by the second transmission gate 414 to the low signaling state. After the fifth point in time 514, the D_{OUT} signal 430 is driven by the first transmission gate 414, which propagates the D_{IN0}* signal 426. However, the D_{IN0} signal 422 does not propagate through the first flipflop 402 until a sixth point in time 516 and the first transmission gate 414 drives the D_{OUT} signal 430 to the high signaling state until the D_{IN0} signal 422 has propagated through the first flipflop 402. The difference between propagation time through the flipflops 402, 404 and propagation time through the transmission gates 412, 414 and may cause a signaling spike 518 in the D_{OUT} signal 430. The duration of the signaling spike 518 reflects the difference between propagation time through the flipflops 402, 404 and propagation time through the transmission gates 412, 414 and may be sufficient to cause other circuits to switch and thereby unnecessarily consume power. In some implementations, the signaling spike 518 may compromise hold or setup times in high-speed interfaces.

Certain aspects of this disclosure can suppress glitches in the D_{OUT} signal 430. The multipath circuit 400 is an example of a structure that is commonly employed in SERDES implementations and the concepts described herein are applicable in a wide range of applications that employ sequential logic circuits.

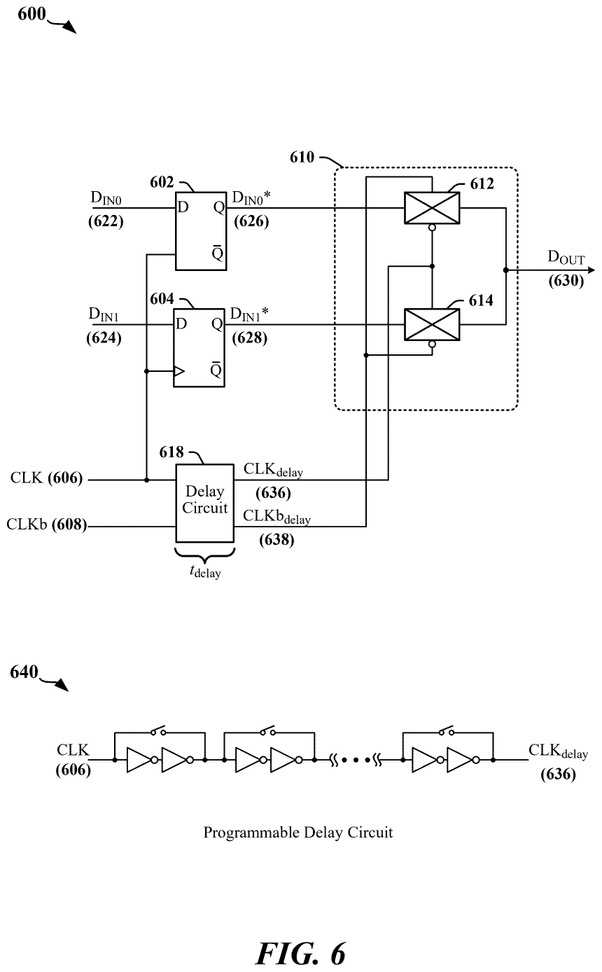

FIG. 6 illustrates certain aspects of a multipath circuit 600 provided in accordance with certain aspects of this disclosure. In one example, the multipath circuit 600 may be included in a muti-path serializer, in which even and odd bits are propagated through flipflops deployed in corresponding even and odd paths and combined using a multiplexer. The illustrated multipath circuit 600 includes two flipflops 602, 604 and a multiplexing circuit 610 that is implemented using transmission gates 612, 614.

The flipflops 602, 604 may operate in a manner that corresponds in some respects to the manner in which the flipflops 402, 404 in FIG. 4 are operated. In the illustrated multipath circuit 600, a first flipflop 602 is configured to capture the signaling state of a D_{IN0} signal 622 at rising edges of a CLK signal 606, and a second flipflop 604 is configured to capture the signaling state of a D_{IN1} signal 624, also at the rising edges of the CLK signal 606. A first data bitstream encoded in the D_{IN0} signal 622 includes even data bits extracted from a parallel data element and a second data bitstream encoded in the D_{IN1} signal 624 includes odd data bits extracted from the parallel data element. In one example, the parallel data element is a 16-bit, 32-bit or 64-bit word. In another example, the parallel data element is an 8-bit byte or 4-bit nibble. Other sized data elements may be serialized using the multipath circuit 600. The first flipflop 602 outputs a sampled version of the first data bitstream in the D_{IN0}*signal 626, which is provided to the input of a first transmission gate 612. The second flipflop 604 outputs a sampled version of the second data bitstream in the D_{IN1}*signal 628, which is provided to the input of a second transmission gate 614. The outputs of the transmission gates 612, 614 are coupled to an output of the multipath circuit 600 through which a D_{OUT} signal 630 is transmitted.

In the illustrated example, the CLK signal 606 and the CLKb signal 608 are half-rate clock signals, having a period that is twice the duration of the UI in which a data bit can be encoded in the D_{OUT} signal 630 that is output by the multipath circuit 600. In other words, the frequency of the CLK signal 606 and the CLKb signal 608 is half the frequency of a data clock signal used to transmit or receive bits of data over a communication link.

A first transmission gate 612 is enabled when a first clock signal (the CLK_{delay} signal 636) is in a first signaling state. The CLK_{delay} signal 636 is a delayed version of the CLK signal 606. A second transmission gate 614 is enabled when a second clock signal (the CLKb_{delay} signal 638 is in a first signaling state. The CLKb_{delay} signal 638 is a delayed version of the CLKb signal 608. In the illustrated example, the CLKb_{delay} signal 638 is phase shifted by 180° with respect to the CLK_{delay} signal 636 and may be referred to as an inverted version of the CLK_{delay} signal 636.

In the illustrated multipath circuit 600, the first transmission gate 612 is enabled when the CLK_{delay} signal 636 is in a first signaling state and disabled when the CLK_{delay} signal 636 is in a second signaling state, and the second transmission gate 614 is enabled when the CLKb_{delay} signal 638 is in the first signaling state and disabled when the CLKb_{delay} signal 638 is in the second signaling state. The first transmission gate 612 is configured to couple the output of the first flipflop 602 to the output of the serializer when the first transmission gate 612 is enabled. The second transmission gate 614 is configured to couple the output of the second flipflop 604 to the output of the serializer when the second transmission gate 614 is enabled.

The CLK_{delay} signal 636 and the CLKb_{delay} signal 638 may be generated by a delay circuit 618 using a small number of buffers or inverters. The number of buffers or inverters may be fixed in some implementations and selectable in other implementations. The delay circuit 618 may be programmable. FIG. 6 incudes an example of a programmable delay circuit 640 that permits the duration of the delay between the CLK signal 606 and the CLK_{delay} signal 636 to be selected by controlling the number of bypass switches that are closed in the programmable delay circuit 640. In other implementations, delays may be introduced by changing the drive characteristics of a clock buffer circuit to slow or accelerate transitions in the clock signal.

The delay introduced between the CLK signal 606 and the CLK_{delay} signal 636 and/or between the CLKb signal 606 and the CLKb_{delay} signal 636 may be selected to match the propagation delays through the first flipflop 602 and the first transmission gate 612 and/or to match the propagation delays through the second flipflop 604 and the second transmission gate 614. The delay used to produce the CLK_{delay} signal 636 and/or the CLKb_{delay} signal 636 may be selected to accommodate signaling delays attributable to sources other than the finite clock edge to data output delay associated with flipflops. For example, the delay between the CLK signal 606 and the CLK_{delay} signal 636 may include parasitic delays associated with signal routing and/or loading, channel characteristics and the effects of parasitic capacitances, inductances and/or resistances. In one example, transitions in a signal used to drive multiple circuits may be slowed with respect to a comparable signal that is used to drive a single circuit.

The delay introduced between the CLK signal 606 and the CLK_{delay} signal 636 may change due to variations in manufacturing process, circuit supply voltage, and die temperature (PVT). Different propagation delays may be observed at different PVT corners. For the purposes of this disclosure, PVT corners represent limits of process, voltage, or temperature and/or combinations thereof. PVT corners may be correlated with limits of operational characteristics of a circuit, including current, voltage, temperature, switching frequency, rise time, fall time, and other characteristics. In some implementations, the delay between the CLK signal 606 and the CLK_{delay} signal 636 may be provided by a small number of inverters that are fabricated using the same type of devices found in the flipflops 602, 604. The inverters may have similar driving strength and the effects of PVT variations on similar devices in the flipflops 602, 604 may be mitigated when comparable changes in performance of the inverters are expected.

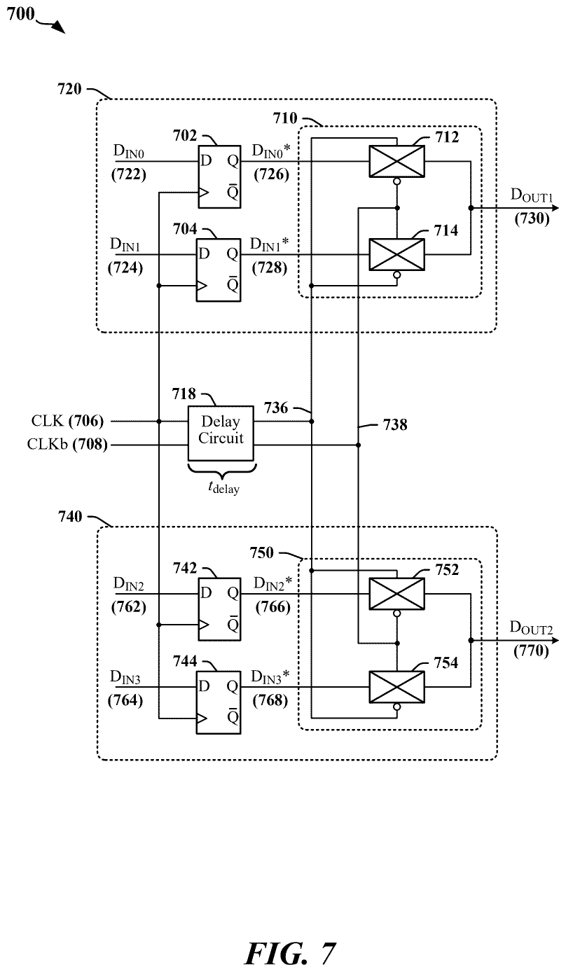

FIG. 7 illustrates a multipath circuit 700 that can mitigate propagation delay differences in a multichannel a high-speed communication link implemented in accordance with certain aspects of this disclosure. In some applications, propagation delay mismatches between multiplexers and sequential logic circuits may have similar effect on multiple channels in a communication interface when, for example, the same clock signals and circuit architectures are employed for each of these channels. In some implementations, the delayed clock signals generated for the multipath circuit 600 illustrated in FIG. 6 can be used by multiple multipath circuits.

The illustrated multipath circuit 700 provides an example in which multiplexed data may be processed using two multipath subcircuits 720, 740 that are controlled by a common set of clock signals. The clock signals include a CLK signal 706 used to control flipflops 702, 704, 742, 744, a CLKb signal 706 that is an inverted version of the CLK signal 706, a CLK_{delay} signal 736 that is a delayed version of the CLK signal 706 and a CLKb_{delay} signal 738 that is a delayed, inverted version of the CLK signal 706. In one example, the CLKb_{delay} signal 738 may be generated as an inverted version of the CLK_{delay} signal 736. In another example, the CLKb_{delay} signal 738 may be generated by independently delaying the CLKb signal 708.

In each multipath subcircuit 720, 740, even and odd bits are propagated through flipflops deployed in corresponding even and odd paths and combined using respective multiplexers. The first multipath subcircuit 720 includes two flipflops 702, 704 and a multiplexing circuit 710 that is implemented using transmission gates 712, 714. The second multipath subcircuit 740 includes two flipflops 742, 744 and a multiplexing circuit 750 that is implemented using transmission gates 752, 754.

In the first multipath subcircuit 720, flipflop 702 is configured to capture the signaling state of a D_{IN0} signal 722 at rising edges of the CLK signal 706, and flipflop 704 is configured to capture the signaling state of a D_{IN1} signal 724, also at the rising edges of the CLK signal 706. A first data bitstream encoded in the D_{IN0} signal 722 includes even data bits extracted from a first parallel data element and a second data bitstream encoded in the D_{IN1} signal 724 includes odd data bits extracted from the first parallel data element. Flipflop 702 outputs a sampled version of the first data bitstream in the D_{IN0}*signal 726 to the input of transmission gate 712, while flipflop 704 outputs a sampled version of the second data bitstream in the D_{IN1}*signal 728 to the input of transmission gate 714. The outputs of the transmission gates 712, 714 are coupled to a first output of the multipath circuit 700 through which a D_{OUT1} signal 730 is transmitted.

Transmission gate 712 is enabled when the CLK_{delay} signal 736 is in a first signaling state and the CLKb_{delay} signal 738 is in a second signaling state. Transmission gate 712 is disabled when the CLK_{delay} signal 736 is in the second signaling state and the CLKb_{delay} signal 738 is in the first signaling state. The output of the first flipflop 702 is coupled to the output of the serializer when transmission gate 712 is enabled. Transmission gate 714 is enabled when the CLKb_{delay} signal 738 is in the first signaling state and the CLK_{delay} signal 736 is in the second signaling state. Transmission gate 714 is disabled when the CLKb_{delay} signal 738 is in the second signaling state and the CLK_{delay} signal 736 is in the first signaling state. The output of the second flipflop 704 is coupled to the output of the serializer when transmission gate 714 is enabled.

In the second multipath subcircuit 740, flipflop 742 is configured to capture the signaling state of a D_{IN2} signal 762 at rising edges of the CLK signal 706, and flipflop 744 is configured to capture the signaling state of a D_{IN3} signal 764 at rising edges of the CLK signal 706. A third data bitstream is encoded in the D_{IN2} signal 762 and includes even data bits extracted from a second parallel data element and a fourth data bitstream is encoded in the D_{IN3} signal 764 and includes odd data bits extracted from the second parallel data element. Flipflop 742 outputs a sampled version of the first data bitstream in the D_{IN2}*signal 766 to the input of transmission gate 752, while flipflop 744 outputs a sampled version of the second data bitstream in the D_{IN3}* signal 768 to the input of transmission gate 754. The outputs of the transmission gates 752, 754 are coupled to a second output of the multipath circuit 700 through which a D_{OUT2} signal 770 is transmitted.

Transmission gate 752 is enabled when the CLK_{delay} signal 736 is in a first signaling state and the CLKb_{delay} signal 738 is in a second signaling state. Transmission gate 752 is disabled when the CLK_{delay} signal 736 is in the second signaling state and the CLKb_{delay} signal 738 is in the first signaling state. The output of the first flipflop 742 is coupled to the output of the serializer when transmission gate 752 is enabled. Transmission gate 754 is enabled when the CLKb_{delay} signal 738 is in the first signaling state and the CLK_{delay} signal 736 is in the second signaling state. Transmission gate 754 is disabled when the CLKb_{delay} signal 738 is in the second signaling state and the CLK_{delay} signal 736 is in the first signaling state. The output of the second flipflop 744 is coupled to the output of the serializer when transmission gate 754 is enabled.

The CLK_{delay} signal 736 and the CLKb_{delay} signal 738 may be generated by a delay circuit 718 using a small number of buffers or inverters. The number of buffers or inverters may be fixed or selectable in different implementations. In other implementations, delays may be introduced by changing the drive characteristics of a clock buffer circuit to slow transitions in the clock signal. In some implementations, the CLK signal 706 and the CLKb signal 706 may be delayed by a duration comparable to a propagation delay through one of the flipflops 702, 704, 742, 744. In other implementations, the CLK signal 706 and the CLKb signal 706 may be delayed by a duration calculated or calibrated to accommodate a difference in propagation delays through the flipflops 702, 704, 742, 744 and corresponding transmission gates 712, 714, 752, 754. In one example, the delay introduced between the CLK signal 706 and the CLK_{delay} signal 736 may be selected to match the propagation delays through the first flipflop 702 and the first transmission gate 712. The delay between the CLKb signal 706 and the CLKb_{delay} signal 736 may be selected to match the propagation delays through the second flipflop 704 and the second transmission gate 714.

In some implementations, the delay introduced between the CLK signal 706 and the CLK_{delay} signal 736 may be selected to accommodate signaling delays attributable to sources other than the finite clock edge to data output delay associated with flipflops. For example, the delay between the CLK signal 706 and the CLK_{delay} signal 736 may include parasitic delays associated with signal routing and/or loading, channel characteristics and the effects of parasitic capacitances, inductances and/or resistances. In one example, transitions in a signal used to drive multiple circuits may be slowed with respect to a comparable signal that is used to drive a single circuit.

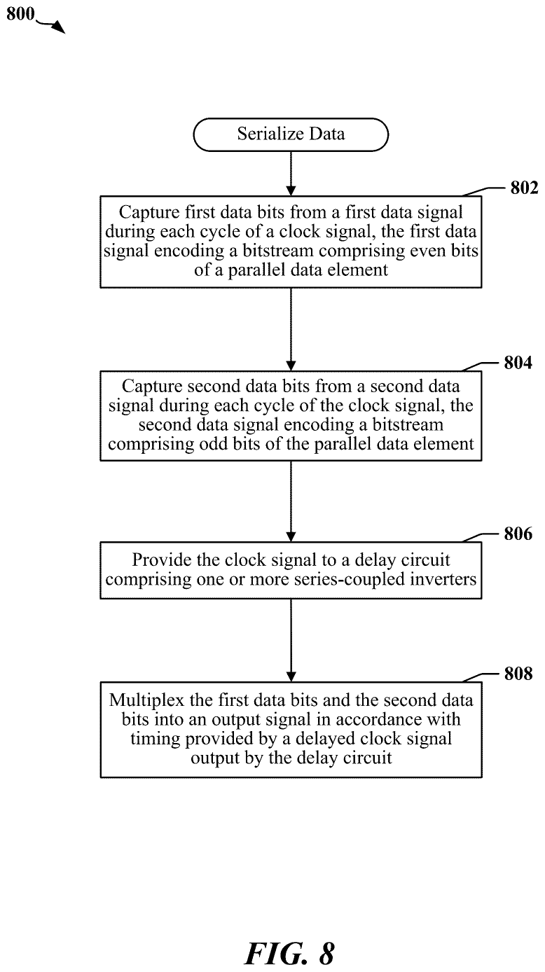

FIG. 8 is a flow diagram illustrating an example of a method 800 for serializing data in accordance with certain aspects disclosed herein. The method may be performed in a high-speed communication interface. In certain implementations, the method 800 may be performed using SERDES circuits that perform in data transmission using half-rate clock signals. For example, the method 800 may be performed using the multipath circuit 600 illustrated in FIG. 6 or the multipath circuit 700 illustrated in FIG. 7.

At block 802, first data bits may be captured from a first data signal during each cycle of a clock signal. The first data signal may encode or carry a bitstream comprising even bits of a parallel data element. At block 804, second data bits may be from a second data signal during each cycle of the clock signal. The second data signal may encode or carry a bitstream comprising odd bits of the parallel data element. At block 806, the clock signal may be provided as an input to a delay circuit. In one example, the delay circuit may be implemented using series-coupled inverters. In another example, the delay circuit may be implemented by controlling drive strength of one or more buffers or inverters. In some implementations, the duration of the delay may be configurable. At block 808, the first data bits and the second data bits may be multiplexed into an output signal in accordance with timing provided by a delayed clock signal output by the delay circuit.

In some implementations, each of the first data bits may be captured from the first data signal using a first flipflop that responds to the clock signal, and each of the second data bits may be captured from the second data signal using a second flipflop that responds to the clock signal. Multiplexing the first data bits and the second data bits into the output signal may include enabling a first transmission gate coupled to the output of the first flipflop to drive the output signal when the delayed clock signal is in a first signaling state, and enabling a second transmission gate to couple the output of the second flipflop to the output of the apparatus when the delayed clock signal is in a second signaling state. In some implementations, the one or more series-coupled inverters includes a number of inverters calculated to accommodate a propagation delay associated with the first flipflop or the second flipflop.

The operational steps described in any of the exemplary aspects herein are described to provide examples. The operations described may be performed in numerous different sequences other than the illustrated sequences. Furthermore, operations described in a single operational step may actually be performed in a number of different steps. Additionally, one or more operational steps discussed in the exemplary aspects may be combined. It is to be understood that the operational steps illustrated in the flow diagrams may be subject to numerous different modifications as will be readily apparent to one of skill in the art. Those of skill in the art will also understand that information and signals may be represented using any of a variety of different technologies and techniques. For example, data, instructions, commands, information, signals, bits, symbols, and chips that may be referenced throughout the above description may be represented by voltages, currents, electromagnetic waves, magnetic fields or particles, optical fields or particles, or any combination thereof.

The various operations of methods described above may be performed by any suitable means capable of performing the corresponding functions. The means may include various hardware and/or software component(s) and/or module(s), including, but not limited to a circuit, an application-specific integrated circuit (ASIC), or processor. Generally, where there are operations illustrated in figures, those operations may have corresponding counterpart means-plus-function components with similar numbering. In certain aspects, an apparatus includes means for capturing data bits from a plurality of datastreams during each cycle of a clock signal, and means for transmitting the data bits in sequential bit transmission intervals through a first output of the apparatus. The means for transmitting the data bits may be configured to respond to a delayed version of the clock signal. The data bits may be captured from a first data signal that encodes a bitstream comprising even bits of a first parallel data element and a second data signal that encodes a bitstream comprising odd bits of the first parallel data element.

In one example, the means for capturing data bits includes flipflops. A first flipflop may be configured to capture a bit of data from the first data signal during each cycle of the clock signal, and a second flipflop may be configured to capture a bit of data from the second data signal during each cycle of the clock signal. The means for transmitting the data bits may include transmission gates. A first transmission gate may be configured to couple the output of the first flipflop to the first output of the apparatus when the delayed version of the clock signal is in a first signaling state. A second transmission gate may be configured to couple the output of the second flipflop to the first output of the apparatus when the delayed version of the clock signal is in a second signaling state. The delayed version of the clock signal may be configured to suppress data-dependent glitches in the first output of the apparatus, which may be used or further processed by subsequent stages of the apparatus.

In some implementations, the apparatus includes, or is coupled to means for delaying the clock signal to obtain the delayed clock signal. The means for delaying the clock signal may be implemented using one or more inverters. The means for delaying the clock signal may be configured to delay the clock signal by a duration comparable to a propagation delay through the first flipflop or through the second flipflop. For example, the delayed clock signal may be obtained by propagating the clock signal through some number of serially-coupled inverters or buffers, where the aggregate delay through the inverters or buffers is substantially the same as the propagation delay of the first data signal through the first flipflop or the propagation delay of the second data signal through the second flipflop.

In certain implementations, the means for capturing data bits further includes additional flipflops. A third flipflop may be configured to capture a bit of data from a third data signal during each cycle of the clock signal. The third data signal may encode a bitstream comprising even bits of a second parallel data element. A fourth flipflop may be configured to capture a bit of data from a fourth data signal during each cycle of the clock signal. The fourth data signal may encode a bitstream comprising odd bits of the second parallel data element. The means for transmitting the data bits may include additional transmission gates. A third transmission gate may be configured to couple the output of the third flipflop to a second output of the apparatus when the delayed version of the clock signal is in the first signaling state. A fourth transmission gate may be configured to couple the output of the fourth flipflop to the second output of the apparatus when the delayed version of the clock signal is in the second signaling state. The delayed version of the clock signal may be further configured to suppress data-dependent glitches in the second output of the apparatus, which may be used or further processed by subsequent stages of the apparatus.

According to certain aspects of this disclosure, a serializer circuit may be implemented with flipflop and a multiplexing circuit. A first flipflop may be configured to capture a bit of data from a first data signal during each cycle of a clock signal. A second flipflop may be configured to capture a bit of data from a second data signal during each cycle of the clock signal. The multiplexing circuit may be configured to provide an output of the first flipflop as an output of the first multiplexing circuit when a delayed version of the clock signal is in a first signaling state, and provide an output of the second flipflop as the output of the first multiplexing circuit when the delayed version of the clock signal is in a second signaling state. The delayed version of the clock signal may be configured to suppress data-dependent glitches in a first output of the serializer circuit. In some examples, the first output of the serializer circuit is used or further processed by one or more subcircuits of a serial interface circuit that incorporates the serializer circuit. The first data signal may encode even bits of a parallel data element and the second data signal may encode odd bits of the parallel data element.

In some examples, the first multiplexing circuit is implemented using transmission gates. A first transmission gate may be configured to couple the output of the first flipflop to the output of the first multiplexing circuit when the delayed version of the clock signal is in the first signaling state. A second transmission gate may be configured to couple the output of the second flipflop to the output of the first multiplexing circuit when the delayed version of the clock signal is in the second signaling state. The delayed version of the clock signal may be configured to suppress data-dependent glitches in a second output of the serializer circuit. In some examples, the second output of the serializer circuit is used or further processed by one or more subcircuits of the serial interface circuit that incorporates the serializer circuit. In some instances, the clock signal is a differential signal that includes the delayed version of the clock signal and an inverted delayed version of the clock signal.

In certain implementations, an input of a delay circuit is coupled to the clock signal. In these implementations, an output of the delay circuit provides the delayed version of the clock signal. The delay circuit may include one or more inverters. The delay circuit may delay the clock signal by a duration comparable to a propagation delay through the first flipflop or through the second flipflop. The serializer may include additional flipflops. For example, a third flipflop may be configured to capture a bit of data from a third data signal during each cycle of the clock signal and a fourth flipflop may be configured to capture a bit of data from a fourth data signal during each cycle of the clock signal. A second multiplexing circuit may be configured to provide an output of the third flipflop as an output of the second multiplexing circuit when a delayed version of the clock signal is in the first signaling state, and provide an output of the fourth flipflop as the output of the second multiplexing circuit when the delayed version of the clock signal is in the second signaling state. The delayed version of the clock signal may be configured to suppress data-dependent glitches in a second output of the serializer circuit. In some examples, the second output of the serializer circuit is used or further processed by one or more subcircuits of the serial interface circuit that incorporates the serializer circuit. In some implementations, the third data signal encodes even bits of a second parallel data element and the fourth data signal encodes odd bits of the second parallel data element.

In some examples, the second multiplexing circuit is implemented using transmission gates. For example, a third transmission gate configured to couple the output of the third flipflop to the output of the second multiplexing circuit when the delayed version of the clock signal is in the first signaling state, and a fourth transmission gate configured to couple the output of the fourth flipflop to the output of the second multiplexing circuit when the delayed version of the clock signal is in the second signaling state.

Some implementation examples are described in the following numbered clauses:

1. A serializer circuit, comprising: a first flipflop configured to capture a bit of data from a first data signal during each cycle of a clock signal; a second flipflop configured to capture a bit of data from a second data signal during each cycle of the clock signal; and a first multiplexing circuit configured to: provide an output of the first flipflop as an output of the first multiplexing circuit when a delayed version of the clock signal is in a first signaling state; and provide an output of the second flipflop as the output of the first multiplexing circuit when the delayed version of the clock signal is in a second signaling state.

2. The serializer circuit as described in clause 1, wherein the first data signal encodes even bits of a parallel data element and the second data signal encodes odd bits of the parallel data element.

3. The serializer circuit as described in clause 1 or clause 2, wherein the first multiplexing circuit comprises: a first transmission gate configured to couple the output of the first flipflop to the output of the first multiplexing circuit when the delayed version of the clock signal is in the first signaling state; and a second transmission gate configured to couple the output of the second flipflop to the output of the first multiplexing circuit when the delayed version of the clock signal is in the second signaling state.

4. The serializer circuit as described in clause 3, wherein the clock signal is a differential signal that includes the delayed version of the clock signal and an inverted delayed version of the clock signal.

5. The serializer circuit as described in any of clauses 1-4, further comprising: a delay circuit having an input that is coupled to the clock signal and an output that provides the delayed version of the clock signal.

6. The serializer circuit as described in clause 5, wherein the delay circuit comprises one or more serially-coupled inverters that delay the clock signal by a duration comparable to a propagation delay through the first flipflop or through the second flipflop.

7. The serializer circuit as described in clause 5 or clause 6, further comprising: a third flipflop configured to capture a bit of data from a third data signal during each cycle of the clock signal; a fourth flipflop configured to capture a bit of data from a fourth data signal during each cycle of the clock signal; and a second multiplexing circuit configured to: provide an output of the third flipflop as an output of the second multiplexing circuit when a delayed version of the clock signal is in the first signaling state; and provide an output of the fourth flipflop as the output of the second multiplexing circuit when the delayed version of the clock signal is in the second signaling state.

8. The serializer circuit as described in clause 7, wherein the first data signal encodes even bits of a first parallel data element and the second data signal encodes odd bits of the first parallel data element, and wherein the third data signal encodes even bits of a second parallel data element and the fourth data signal encodes odd bits of the second parallel data element.

9. The serializer circuit as described in clause 7 or clause 8, wherein the second multiplexing circuit comprises: a third transmission gate configured to couple the output of the third flipflop to the output of the second multiplexing circuit when the delayed version of the clock signal is in the first signaling state; and a fourth transmission gate configured to couple the output of the fourth flipflop to the output of the second multiplexing circuit when the delayed version of the clock signal is in the second signaling state.

10. An apparatus comprising: means for capturing data bits from a plurality of datastreams during each cycle of a clock signal; and means for transmitting the data bits in sequential bit transmission intervals through a first output of the apparatus, wherein the means for transmitting the data bits is configured to respond to a delayed version of the clock signal, and wherein the data bits are captured from a first data signal that encodes a bitstream comprising even bits of a first parallel data element and a second data signal that encodes a bitstream comprising odd bits of the first parallel data element.

11. The apparatus as described in clause 10, wherein the means for capturing data bits comprises: a first flipflop configured to capture a bit of data from the first data signal during each cycle of the clock signal; and a second flipflop configured to capture a bit of data from the second data signal during each cycle of the clock signal.

12. The apparatus as described in clause 11 or clause 10, wherein the means for transmitting the data bits comprises: a first transmission gate configured to couple the output of the first flipflop to the first output of the apparatus when the delayed version of the clock signal is in a first signaling state; and a second transmission gate configured to couple the output of the second flipflop to the first output of the apparatus when the delayed version of the clock signal is in a second signaling state.

13. The apparatus as described in clause 11 or clause 12, further comprising: means for delaying the clock signal to obtain the delayed clock signal.

14. The apparatus as described in clause 13, wherein the means for delaying comprises one or more inverters and is configured to delay the clock signal by a duration comparable to a propagation delay through the first flipflop or through the second flipflop.

15. The apparatus as described in clause 13 or clause 14, wherein the means for capturing data bits further comprises: a third flipflop configured to capture a bit of data from a third data signal during each cycle of the clock signal, wherein the third data signal encodes a bitstream comprising even bits of a second parallel data element; and a fourth flipflop configured to capture a bit of data from a fourth data signal during each cycle of the clock signal, wherein the fourth data signal encodes a bitstream comprising odd bits of the second parallel data element.

16. The apparatus as described in clause 15, wherein the means for transmitting the data bits further comprises: a third transmission gate configured to couple the output of the third flipflop to a second output of the apparatus when the delayed version of the clock signal is in the first signaling state; and a fourth transmission gate configured to couple the output of the fourth flipflop to the second output of the apparatus when the delayed version of the clock signal is in a second signaling state.

17. A method for serializing data, comprising: capturing first data bits from a first data signal during each cycle of a clock signal, the first data signal encoding a bitstream comprising even bits of a parallel data element; capturing second data bits from a second data signal during each cycle of the clock signal, the second data signal encoding a bitstream comprising odd bits of the parallel data element; providing the clock signal as an input to a delay circuit comprising one or more series-coupled inverters; and multiplexing the first data bits and the second data bits into an output signal in accordance with timing provided by a delayed clock signal output by the delay circuit.

18. The method as described in clause 17, further comprising: capturing each of the first data bits from the first data signal using a first flipflop that responds to the clock signal; and capturing each of the second data bits from the second data signal using a second flipflop that responds to the clock signal.

19. The method as described in clause 18, wherein multiplexing the first data bits and the second data bits into the output signal comprises: enabling a first transmission gate coupled to the output of the first flipflop to drive the output signal when the delayed clock signal is in a first signaling state; and enabling a second transmission gate to couple the output of the second flipflop to the output of the apparatus when the delayed clock signal is in a second signaling state.

20. The method as described in clause 19, wherein the one or more series-coupled inverters includes a number of inverters calculated to accommodate a propagation delay associated with the first flipflop or the second flipflop

The present disclosure is provided to enable any person skilled in the art to make or use aspects of the disclosure. Various modifications to the disclosure will be readily apparent to those skilled in the art, and the generic principles defined herein may be applied to other variations without departing from the spirit or scope of the disclosure. Thus, the disclosure is not intended to be limited to the examples and designs described herein, but is to be accorded the widest scope consistent with the principles and novel features disclosed herein.

What is claimed is:

1. A serializer circuit, comprising:
a first flipflop configured to capture a bit of data from a first data signal during each cycle of a clock signal;
a second flipflop configured to capture a bit of data from a second data signal during each cycle of the clock signal; and
a first multiplexing circuit configured to:
provide an output of the first flipflop as an output of the first multiplexing circuit when a delayed version of the clock signal is in a first signaling state; and
provide an output of the second flipflop as the output of the first multiplexing circuit when the delayed version of the clock signal is in a second signaling state.

2. The serializer circuit of claim 1, wherein the first data signal encodes even bits of a parallel data element and the second data signal encodes odd bits of the parallel data element.

3. The serializer circuit of claim 1, wherein the first multiplexing circuit comprises:
a first transmission gate configured to couple the output of the first flipflop to the output of the first multiplexing circuit when the delayed version of the clock signal is in the first signaling state; and
a second transmission gate configured to couple the output of the second flipflop to the output of the first multiplexing circuit when the delayed version of the clock signal is in the second signaling state.

4. The serializer circuit of claim 3, wherein the clock signal is a differential signal that includes the delayed version of the clock signal and an inverted delayed version of the clock signal.

5. The serializer circuit of claim 1, further comprising:
a delay circuit having an input that is coupled to the clock signal and an output that provides the delayed version of the clock signal.

6. The serializer circuit of claim 5, wherein the delay circuit comprises one or more serially-coupled inverters that delay the clock signal by a duration comparable to a propagation delay through the first flipflop or through the second flipflop.

7. The serializer circuit of claim 5, further comprising:
a third flipflop configured to capture a bit of data from a third data signal during each cycle of the clock signal;
a fourth flipflop configured to capture a bit of data from a fourth data signal during each cycle of the clock signal; and
a second multiplexing circuit configured to:
provide an output of the third flipflop as an output of the second multiplexing circuit when a delayed version of the clock signal is in the first signaling state; and
provide an output of the fourth flipflop as the output of the second multiplexing circuit when the delayed version of the clock signal is in the second signaling state.

8. The serializer circuit of claim 7, wherein the first data signal encodes even bits of a first parallel data element and the second data signal encodes odd bits of the first parallel data element, and wherein the third data signal encodes even bits of a second parallel data element and the fourth data signal encodes odd bits of the second parallel data element.

9. The serializer circuit of claim 7, wherein the second multiplexing circuit comprises:
a third transmission gate configured to couple the output of the third flipflop to the output of the second multiplexing circuit when the delayed version of the clock signal is in the first signaling state; and
a fourth transmission gate configured to couple the output of the fourth flipflop to the output of the second multiplexing circuit when the delayed version of the clock signal is in the second signaling state.

10. An apparatus comprising:
means for capturing data bits from a plurality of datastreams during each cycle of a clock signal; and
means for transmitting the data bits in sequential bit transmission intervals through a first output of the apparatus,
wherein the means for transmitting the data bits is configured to respond to a delayed version of the clock signal, and
wherein the data bits are captured from a first data signal that encodes a bitstream comprising even bits of a first parallel data element and a second data signal that encodes a bitstream comprising odd bits of the first parallel data element.

11. The apparatus of claim 10, wherein the means for capturing data bits comprises:
a first flipflop configured to capture a bit of data from the first data signal during each cycle of the clock signal; and
a second flipflop configured to capture a bit of data from the second data signal during each cycle of the clock signal.

12. The apparatus of claim 11, wherein the means for transmitting the data bits comprises:
a first transmission gate configured to couple the output of the first flipflop to the first output of the apparatus when the delayed version of the clock signal is in a first signaling state; and
a second transmission gate configured to couple the output of the second flipflop to the first output of the apparatus when the delayed version of the clock signal is in a second signaling state.

13. The apparatus of claim 11, further comprising:
means for delaying the clock signal to obtain the delayed clock signal.

14. The apparatus of claim 13, wherein the means for delaying comprises one or more inverters and is configured to delay the clock signal by a duration comparable to a propagation delay through the first flipflop or through the second flipflop.

15. The apparatus of claim 13, wherein the means for capturing data bits further comprises:
a third flipflop configured to capture a bit of data from a third data signal during each cycle of the clock signal, wherein the third data signal encodes a bitstream comprising even bits of a second parallel data element; and
a fourth flipflop configured to capture a bit of data from a fourth data signal during each cycle of the clock signal, wherein the fourth data signal encodes a bitstream comprising odd bits of the second parallel data element.

16. The apparatus of claim 15, wherein the means for transmitting the data bits further comprises:
a third transmission gate configured to couple the output of the third flipflop to a second output of the apparatus when the delayed version of the clock signal is in a first signaling state; and
a fourth transmission gate configured to couple the output of the fourth flipflop to the second output of the apparatus when the delayed version of the clock signal is in a second signaling state.

17. A method for serializing data, comprising:
capturing first data bits from a first data signal during each cycle of a clock signal, the first data signal encoding a bitstream comprising even bits of a parallel data element;
capturing second data bits from a second data signal during each cycle of the clock signal, the second data signal encoding a bitstream comprising odd bits of the parallel data element;
providing the clock signal as an input to a delay circuit comprising one or more series-coupled inverters; and
multiplexing the first data bits and the second data bits into an output signal in accordance with timing provided by a delayed clock signal output by the delay circuit.

18. The method of claim 17, further comprising:
capturing each of the first data bits from the first data signal using a first flipflop that responds to the clock signal; and
capturing each of the second data bits from the second data signal using a second flipflop that responds to the clock signal.

19. The method of claim 18, wherein multiplexing the first data bits and the second data bits into the output signal comprises:
enabling a first transmission gate coupled to the output of the first flipflop to drive the output signal when the delayed clock signal is in a first signaling state; and
enabling a second transmission gate to couple the output of the second flipflop to the output signal when the delayed clock signal is in a second signaling state.

20. The method of claim 19, wherein the one or more series-coupled inverters includes a number of inverters calculated to accommodate a propagation delay associated with the first flipflop or the second flipflop.
